(19) United States
(12) Patent Application Publication
(10) Pub. No.: US 2018/0309002 A1
(43) Pub. Date: Oct. 25, 2018

(54) SOLAR CELL PROTECTIVE SHEET, METHOD FOR PRODUCING SAME, SOLAR CELL MODULE, AND METHOD FOR PRODUCING SAME

(71) Applicant: Hanwha Advanced Materials Corporation, Sejong (KR)

(72) Inventors: Jung Sik BANG, Sejong (KR); Tae Yoon KIM, Sejong (KR); Joo Sub LEE, Sejong (KR)

(73) Assignee: Hanwha Advanced Materials Corporation, Sejong (KR)

(21) Appl. No.: 15/770,603

(22) PCT Filed: Dec. 13, 2016
(86) PCT No.: PCT/KR2016/014600

§ 371 Date: Apr. 24, 2018

(30) Foreign Application Priority Data
Dec. 14, 2015 (KR) 10-2015-0177955
Nov. 22, 2016 (KR) 10-2016-0156074

(51) Int. Cl. H01L 31/049; H01L 31/0224; H01L 31/05; H01L 31/18

(52) U.S. Cl. CPC H01L 31/049; H01L 31/18; H01L 31/05; H01L 31/022425

(57) ABSTRACT

The solar cell protective sheet according to the present invention comprises a polymer layer, and a plurality of electrodes arranged thereon, wherein the plurality of electrodes comprises two or more unit electrodes arranged and separated in a first direction, each unit electrode comprising a cell region and a connecting region.

### TECHNICAL FIELD

The present invention relates to a solar cell protective sheet, a method of fabricating the same, a solar cell module, and a method of fabricating the same.

### BACKGROUND ART

Recently, photovoltaic power generation has attracted attention since it has the advantage of being able to convert sunlight into electricity without environmental problems such as air pollution or global warming.

Photovoltaic power generation requires a solar cell module, which has a multilayer structure including a protective sheet.

A solar cell module (and a protective sheet) includes a plurality of electrodes transmitting current of a solar cell to another adjacent solar cell or an external component. Preferably, the plurality of electrodes has a small area and high conductivity to improve solar cell efficiency.

However, it is more difficult to connect adjacent solar cells to one another with decreasing electrode area. For example, in manufacture of a solar cell, some of the electrodes are likely not to be coupled to one another, causing incomplete electrical connection, or short circuit between the electrodes can occur due to long-term exposure to high temperature or the like.

In addition, in manufacture of a solar cell module using a sheet including electrodes, there is a height difference between a region where a solar cell is present and a region without any solar cell can be created, causing an alignment difference between electrodes connecting adjacent solar cells to one another and thus causing improper or incomplete connection between the electrodes.

Therefore, there is a need for a solar cell protective sheet and solar cell module which can allow stable connection between electrodes connecting adjacent solar cells to one another and can minimize the height difference between the electrodes, thereby exhibiting high reliability.

The background technique of the present invention is disclosed in Korean Patent Laid-open Publication No. 2006-0101483.

### DISCLOSURE

### Technical Problem

It is one object of the present invention to provide a solar cell module which allows stable connection between electrodes connecting adjacent solar cells to one another, a method of fabricating the same, and a solar cell protective sheet.

It is another object of the present invention to provide a solar cell module which can minimize a height difference between electrodes connecting adjacent solar cells to one another, thereby improving reliability in connection between the electrodes, a method of fabricating the same, and a solar cell protective sheet.

It is still another object of the present invention to provide a solar cell module which can conceal electrodes connecting adjacent solar cells to one another, thereby exhibiting improved appearance, a method of fabricating the same, and a solar cell protective sheet.

These and other objects of the present invention can be achieved by embodiments of the present invention described below.

### Technical Solution

One aspect of the present invention relates to a solar cell protective sheet.

The solar cell protective sheet includes: a polymer layer; and a plurality of electrodes arranged on the polymer layer, wherein the plurality of electrodes includes at least two unit electrodes arranged separately from one another in a first direction, wherein each of the unit electrodes is composed of a cell section and a connecting section.

The electrode may include a protrusion formed at one end of the connecting section thereof and extending in a second direction.

The plurality of electrodes may include at least two line electrodes arranged separate from one another in the second direction, wherein each of the line electrodes may include at least two unit electrodes arranged separate from one another in the first direction.

The connecting section may include at least one portion not parallel to the first direction.

A unit electrode of a first line electrode and a unit electrode of a second line electrode may be connected to one another at the connecting sections thereof.

The cell section may include at least one portion not parallel to the first direction.

The unit electrode of the first line electrode and the unit electrode of the second line electrode may be connected to one another in a semicircular shape at the connecting sections thereof, and the unit electrode of the second line electrode and a unit electrode of another adjacent line electrode may be connected to one another in a semicircular shape at the connecting sections thereof, wherein the unit electrodes may be integrally formed with one another in the second direction.

The polymer layer may include at least one selected from among an ethylene-vinyl acetate resin, a polyolefin resin, a polyester resin, a polyurethane resin, an ethylene copolymer resin, a silicone compound, and a silicone-based hybrid copolymer.

The electrode may include a conductor and a conductive material formed on the conductor, wherein the conductive material may include an alloy having a melting point of 200° C. or less.

The conductor may include copper (Cu), nickel (Ni), aluminum (Al), or at least two selected from copper (Cu), nickel (Ni), aluminum (Al), an anisotropic conductive film, anisotropic conductive pastes (CP), and activated carbon fiber (ACF).

The alloy having a melting point of 200° C. or less may be an alloy of at least two selected from among bismuth (Bi), tin (Sn), silver (Ag), lead (Pb), cadmium (Cd), and indium (In).

The conductive material may be formed on a portion or the entirety of an outer surface of the conductor.

The plurality of electrodes may be formed on the polymer layer through a bonding agent.

The bonding agent may be formed on a portion or the entirety of an outer surface of the electrode.

The solar cell protective sheet may further include a shielding member interposed between the connecting section and the polymer layer, wherein the shielding member may extend in the second direction.

The shielding member may include at least one selected from among polyethylene terephthalate (PET), polypropylene (PP), polyimide (PI), poly(methyl methacrylate) (PMMA), polystyrene (PS), polyethylene (PE), polyvinylchloride (PVC), and ethylene vinyl acetate (EVA).

Another aspect of the present invention relates to a method of fabricating a solar cell protective sheet.

The method may include laminating a plurality of electrodes on a polymer layer.

A further aspect of the present invention relates to a solar cell module.

The solar cell module may include: a first protective sheet; a second protective sheet opposite the first protective sheet; and at least two solar cells formed between the first protective sheet and the second protective sheet, wherein the first protective sheet or the second protective sheet may include the solar cell protective sheet set forth above.

The connecting section of the first protective sheet may be electrically connected to the connecting section of the second protective sheet contacting a solar cell adjacent to the connecting section of the first protective sheet.

Yet another aspect of the present invention relates to a method of fabricating a solar cell module.

The method may include: arranging at least two solar cells on a second protective sheet; placing a first protective sheet on the second protective sheet and the solar cells; and laminating the second protective sheet, the solar cells, and the first protective sheet at a temperature of 200° C. or less.

### Advantageous Effects

The present invention provides a solar cell module which allows stable connection between electrodes connecting adjacent solar cells to one another, can minimize a height difference between the electrodes, thereby improving reliability in connection between the electrodes, and can conceal the electrodes, thereby exhibiting improved appearance, a method of fabricating the same, and a solar cell protective sheet.

### DESCRIPTION OF DRAWINGS

FIG. 1 is a schematic plan view of a solar cell protective sheet according to one embodiment of the present invention.

FIG. 2 is a schematic plan view of a solar cell protective sheet according to another embodiment of the present invention.

FIG. 3 is a schematic sectional view of the solar cell protective sheet according to another embodiment of the present invention.

FIG. 4 is a schematic plan view of a solar cell protective sheet according to a further embodiment of the present invention.

FIG. 5 is a schematic plan view of a solar cell protective sheet according to yet another embodiment of the present invention.

FIG. 6 is a perspective view of an arrangement of electrodes of the solar cell protective sheet according to another embodiment of the present invention when the solar cell protective sheet is used in a solar cell module.

FIG. 7 is a schematic plan view of a solar cell protective sheet according to yet another embodiment of the present invention.

FIG. 8 is a schematic plan view of a solar cell protective sheet according to yet another embodiment of the present invention.

FIG. 9 is a schematic plan view of a solar cell protective sheet according to yet another embodiment of the present invention.

FIG. 10 is a schematic plan view of a solar cell protective sheet according to yet another embodiment of the present invention.

FIG. 11 is a schematic plan view of a solar cell protective sheet according to yet another embodiment of the present invention.

FIG. 12 is a schematic sectional view of an electrode according to one embodiment of the present invention.

FIG. 13 is a schematic sectional view of an electrode according to another embodiment of the present invention.

FIG. 14 is a schematic sectional view of a solar cell protective sheet according to yet another embodiment of the present invention.

FIG. 15 is a schematic sectional view of a solar cell module in which the solar cell protective sheet according to yet another embodiment of the present invention is used.

FIG. 16 is a schematic sectional view of a solar cell module according to one embodiment of the present invention.

### BEST MODE

Hereinafter, embodiments of the present invention will be described with reference to the accompanying drawings. It should be understood that the present invention is not limited to the following embodiments and may be embodied in different ways.

In addition, it should be understood that the embodiments are provided for complete disclosure and thorough understanding of the present invention by those skilled in the art. In the drawings, thicknesses or widths of various components of each device may be exaggerated for convenience. Further, although only a portion of a component is shown for convenience, the other portions of the component will be readily understood by those skilled in the art.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present.

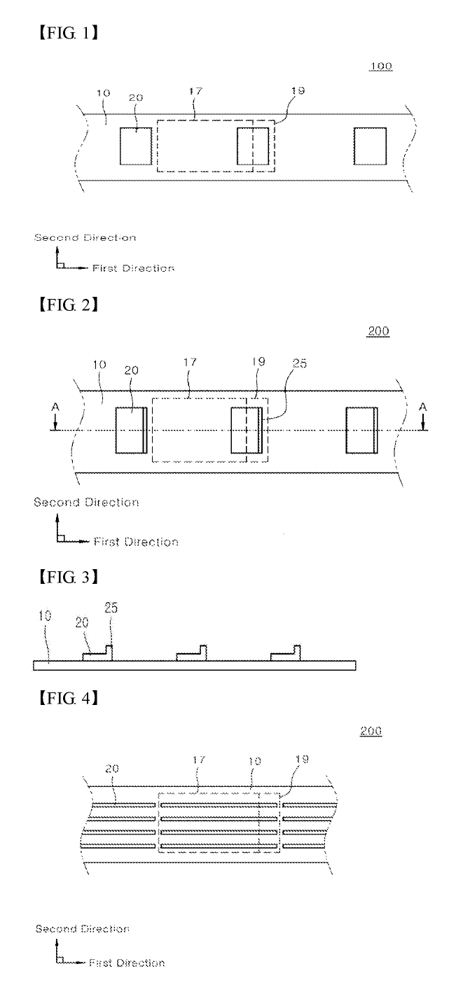

As used herein, the term “first direction” refers to a first direction shown in FIG. 2, and the term “second direction” is defined as a direction perpendicular to the first direction.

As used herein, the term “cell section” refers to a section of a unit electrode which contacts a solar cell in manufacture of a solar cell module.

As used herein, the term “connecting section” refers to a section of the unit electrode other than the cell section, which connects adjacent solar cells to one another in manufacture of a solar cell module.

As used herein, the term “parallel” means “parallel on the same plane as the cell section”, and, as for a curve, may mean “parallel to the tangential direction of the curve”.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section.

In addition, it should be understood that various modifications, changes, alterations, and equivalent embodiments can be made by those skilled in the art without departing from the spirit and scope of the invention. Like components will be denoted by like reference numerals throughout the specification.

As used herein, the singular forms, “a,” “an,” and “the” are intended to include the plural forms as well, unless context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In addition, in carrying out a method or a manufacturing method, steps of the method may occur in an order different from an order described herein unless a specific order is clearly stated in context. In other words, the steps of the method may be performed in the same order as described, may be performed at substantially the same time, or may be performed in reverse order.

Now, exemplary embodiments of the present invention will be described.

Solar cell protective sheet

A solar cell protective sheet according to one embodiment of the present invention will be described with reference to FIG. 1. FIG. 1 is a schematic plan view of a solar cell protective sheet according to one embodiment of the present invention.

The solar cell protective sheet 100 according to the present invention includes a polymer layer 10 and a plurality of electrodes 20 arranged on the polymer layer 10, wherein the plurality of electrodes 20 includes at least two unit electrodes arranged separate from one another in the first direction and each of the unit electrodes is composed of a cell section 17 and a connecting section 19.

Now, each component of the solar cell protective sheet will be described in detail.

The polymer layer 10 serves to protect a solar cell and may form a laminate together with the plurality of electrodes 20. Specifically, the plurality of electrodes 20 may be formed on the polymer layer 10 through a bonding agent or an adhesive. Alternatively, the polymer layer 10 may be heated to become viscous to allow the plurality of electrodes 20 to be secured thereto.

The polymer layer 10 may include at least one selected from among an ethylene-vinyl acetate resin, a polyolefin resin, a polyester resin, a polyurethane resin, an ethylene copolymer resin, a silicone compound, and a silicone-based hybrid copolymer. Here, the silicone compound may be a silicone compound other than the silicone-based hybrid copolymer and may include at least one selected from among, for example, polydimethyl siloxane (PDMS), polymethylethyl siloxane, polydiethyl siloxane, polydiphenylsiloxane, and polyethylphenylsiloxane. The silicone-based hybrid copolymer may be obtained by polymerization of at least one of the silicone compound with at least one of an olefin compound, an ester compound, and a urethane compound.

In order to facilitate the lamination process, the entire surface of the polymer layer may be embossed, or a portion of the surface of the polymer layer, excluding a portion of the surface on which the plurality of electrodes will be formed, may be embossed, without being limited thereto.

In addition, the polymer layer 10 may include at least one selected from among a high-thermal conductivity insulation material, a heat dissipation material, a transparent material, an antioxidant, a UV absorber, a heat-polymerizable material, and a photo-conversion material. For example, the polymer layer 10 may include a material that allows incident sunlight to be reflected by an inner surface of the polymer layer so as to increase absorption of sunlight.

The plurality of electrodes 20 serves to transmit current reaching an electrode of a solar cell to another adjacent solar cell or an external component. Referring to FIG. 1, the plurality of electrodes 20 may include at least two unit electrodes arranged at constant intervals in the first direction. In one embodiment, each of the plurality of electrodes may be in pad form, as shown in FIG. 1.

Each of the unit electrodes 20 includes the cell section 17 and the connecting section 19. Here, the cell section 17 refers to a section of the unit electrode which contacts a solar cell in manufacture of a solar cell module, and the connecting section 19 refers to a section of the unit electrode other than the cell section, which connects adjacent solar cells to one another in manufacture of a solar cell module.

Since the solar cell protective sheet 100 according to the present invention includes the plurality of electrodes formed on the polymer layer 10 and each including the cell section 17 and the connecting section 19, adjacent solar cells can be electrically connected to one another through a simple process in manufacture of a solar cell module and a light receiving area of the solar cell can be maximized.

Next, a solar cell protective sheet according to another embodiment of the present invention will be described with reference to FIG. 2 and FIG. 3. FIG. 2 is a schematic plan view of a solar cell protective sheet according to another embodiment of the present invention and FIG. 3 is a schematic sectional view of the solar cell protective sheet according to another embodiment.

In this embodiment, the electrode of the solar cell protective sheet 200 may include a protrusion 25 formed at one end of the connecting section 19 and extending in the second direction. The protrusion 25 may be formed separate from the electrode or may be integrally formed with the electrode. The protrusion 25 serves to minimize a height difference between electrodes caused by a solar cell in manufacture of a solar cell module, thereby allowing a stable solar cell module manufacturing process while improving durability of the solar cell module.

Next, a solar cell protective sheet according to a further embodiment of the present invention will be described with reference to FIG. 4. FIG. 4 is a schematic plan view of a solar cell protective sheet according to this embodiment.

In the solar cell protective sheet 300 according to this embodiment, the plurality of electrodes 20 may include at least two line electrodes arranged separate from one another in the second direction, wherein each of the line electrodes may include at least two unit electrodes arranged at constant intervals D in the first direction. The solar cell protective sheet according to this embodiment, which includes the plurality of electrodes 20 including the line electrodes, can increase the area of a solar cell receiving sunlight and can minimize short-circuit between electrodes through discrete distribution of the cell sections 17 of the electrodes.

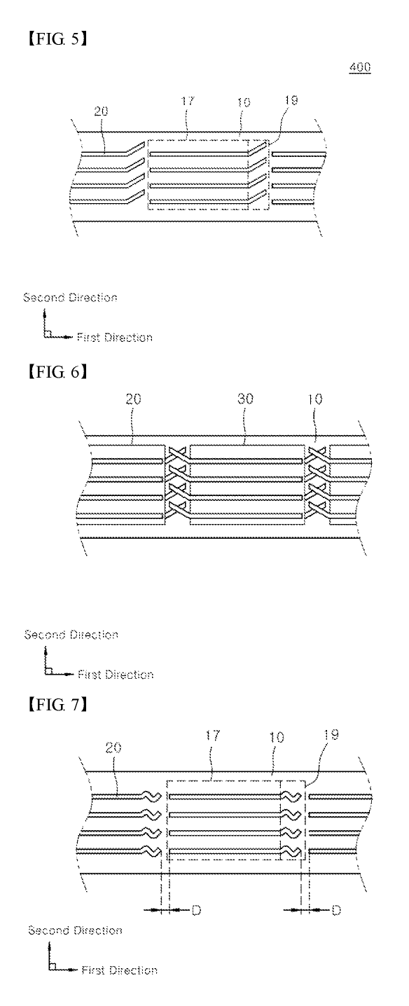

Next, a solar cell protective sheet according to yet another embodiment of the present invention will be described with reference to FIG. 5 and FIG. 6. FIG. 5 is a schematic plan view of a solar cell protective sheet according to yet another embodiment and FIG. 6 is a perspective view of the arrangement of electrodes of the solar cell protective sheet according to yet another embodiment when the solar cell protective sheet is used in a solar cell module.

In the solar cell protective sheet 400 according to this embodiment, the connecting section may include at least one portion that is not parallel to the first direction. In the solar cell protective sheet 400, the electrode includes, at the connecting section thereof 19, at least one portion not parallel to the first direction and thus can be stably connected to an electrode of an adjacent solar cell through a simple process, thereby minimizing defects. Here, the term “parallel” means “parallel on the same plane as the cell section”, and, as for a curve, may mean “parallel to the tangential direction of the curve”.

Specifically, the structure in which the electrode includes, at the connecting section 19 thereof, at least one portion not parallel to the first direction may include any structure in which the electrodes can be easily connected to one another at the connecting sections 19 thereof. In manufacture of a solar cell module, the solar cell protective sheet 400 is stacked upside down on another solar cell protective sheet such that nonparallel portions of the respective solar cell protective sheets cross one another, whereby stable connection between the electrodes can be achieved through a simple process, thereby minimizing defects.

Referring to FIG. 5, the electrode may be, at the connecting section 19 thereof, in the form of a straight line not parallel to the first direction. Specifically, the connecting section 19 may be in the form of an oblique line. In manufacture of a solar cell module using the solar cell protective sheet including the connecting section set forth above, the electrodes overlap one another in an X-shape at the connecting sections thereof and thus can be stably connected to one another through a simple process (see FIG. 6).

In a further example, the connecting section may have a wave shape, as shown in FIG. 7. In this case, the connecting section 19 is connected at at least two portions thereof to another connecting section, whereby corresponding electrodes can be more reliably connected to one another.

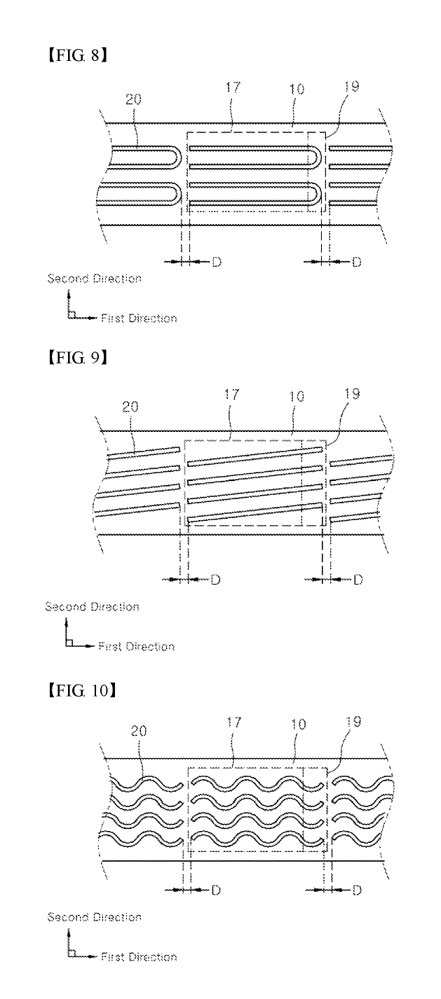

In yet another example, a unit electrode of a first line electrode and a unit electrode of a second line electrode adjacent to the first line electrode may be connected to one another at the connecting sections thereof, as shown in FIG. 8.

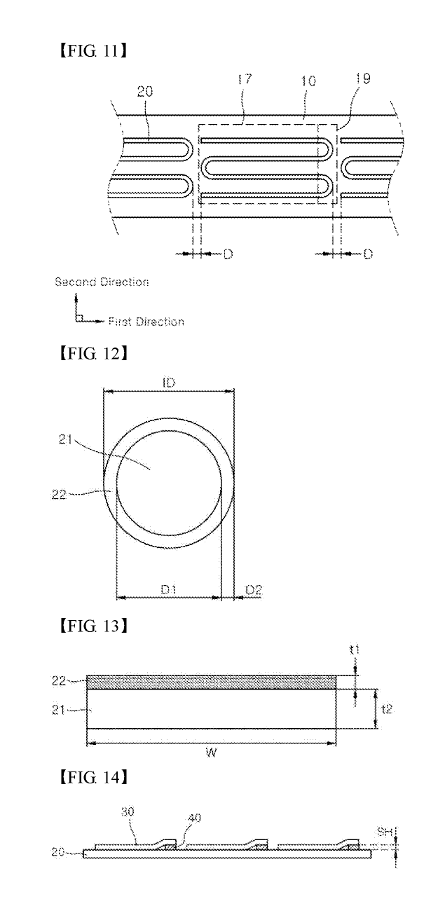

In yet another example, the electrode may include, at the cell section 17 thereof, at least one portion that is not parallel to the first direction, as shown in FIG. 9 to FIG. 11. When the electrode includes, at both the connecting section 19 and the cell section 17 thereof, at least one portion that is not parallel to the first direction, an electrode-forming process can be easy and simple. Specifically, the cell section and the connecting section of the electrode may have an oblique line shape (See FIG. 9) or a wave shape (see FIG. 10). Alternatively, unit electrodes of different line electrodes may be connected to one another, as shown in FIG. 11. For example, a unit electrode of a first line electrode and a unit electrode of a second line electrode may be connected to one another in a semicircular shape at the connecting sections thereof, and the unit electrode of the second line electrode and a unit electrode of another adjacent line electrode may be connected to one another in a semicircular shape at the connecting sections thereof, wherein the unit electrodes may be integrally formed with one another in the second direction.

Next, the electrode according to the present invention will be described in more detail with reference to FIG. 12 and FIG. 13. FIG. 12 is a schematic sectional view of an electrode according to one embodiment of the present invention and FIG. 13 is a schematic sectional view of an electrode according to another embodiment of the present invention.

Referring to FIG. 12 and FIG. 13, the electrode according to the present invention includes a conductor 21 and a conductive material 22 formed on the conductor 21, wherein the conductive material 22 may include an alloy having a melting point of 200° C. or less, specifically 100° C. to 200° C. Here, the alloy having a melting point of 200° C. or less may be laminated or coated on the conductor. When the electrode includes the conductive material having a melting point of 200° C. or less, the electrode can be coupled and electrically connected to an electrode of an adjacent solar cell through a process performed at a temperature of 200° C. or less, specifically 100° C. to 200° C., more specifically 150° C. to 200° C., thereby exhibiting high processability.

Referring to FIG. 12 and FIG. 13, the conductor 21 may have a ribbon or wire shape. Here, the conductor 21 may have a width W of 50 μm to 2 mm, a thickness t₂ of 50 μm to 2 mm and a diameter D1, D2 of 50 μm to 2 mm, without being limited thereto. For example, a product of the width W or diameter D1 of the conductor 21 and the number of electrodes arranged in the second direction (wherein the electrodes each extend in the first direction) may range from 2.5 mm to 5.5 mm (see Equation 1), specifically 3.5 mm to 4.5 mm.

2.5 mm≤Width W or diameter D1 of the conductor×number of electrodes arranged in the second direction≤5.5 mm <Equation 1>

Within this range, both solar cell efficiency and alignment between electrode patterns can be good.

When the conductor 21 has a wire shape, as shown in FIG. 12, the conductor 21 may have a diameter D1 of 50 μm to 500 μm. Here, the conductive material 22 formed on the conductor 21 may have a thickness D2 of 10 μm or less, without being limited thereto.

When the conductor 21 has a ribbon shape, as shown in FIG. 13, the conductor 21 may have a thickness t₂ of 50 μm to 100 μm and a width W of 200 μm to 500 μm. Here, the conductive material 22 formed on the conductor 21 may have a thickness t₁ of 10 μm or less, without being limited thereto.

For example, the plurality of electrodes may include 2 to 50 electrodes arranged in the second direction (a direction perpendicular to the first direction). Specifically, when the plurality of electrodes has a ribbon shape, the plurality of electrodes may include 2 to 10 electrodes arranged in the second direction, and, when the plurality of electrodes has a wire shape, the plurality of electrodes may include 5 to 50 electrodes arranged in the second direction. Within this range, solar cell efficiency can be good.

The conductor 21 may include copper (Cu), nickel (Ni), aluminum (Al), or at least two selected from copper (Cu), nickel (Ni), aluminum (Al), an anisotropic conductive film, anisotropic conductive pastes (CP), and activated carbon fiber (ACF). When the conductor includes at least two metals, the conductor may be an alloy of the metals.

The alloy having a melting point of 200° C. or less, specifically 100° C. to 200° C., which is used as the conductive material 22, may be an alloy of at least two selected from among bismuth (Bi), tin (Sn), silver (Ag), lead (Pb), cadmium (Cd), and indium (In).

The conductive material 22 may be formed on a portion or the entirety of an outer surface of the conductor 21. For example, when the electrode has a circular shape in cross section, the conductive material 22 may be formed on the entire outer surface of the conductor 21, as shown in FIG. 12, or may be formed on a portion (not shown) of the outer surface of the conductor 21. When the electrode has a rectangular shape in cross section, the conductive material 22 may be formed on a portion of the outer surface of the conductor 21 (for example, on one side or three sides (not shown) of the conductor), as shown in FIG. 13, or may be formed on the entire outer surface of the conductor 21 (for example, on all of four sides (not shown) of the conductor).

In one embodiment, the solar cell protective sheet according to the present invention may further include a bonding agent or an adhesive (not shown) between the electrode and the polymer layer. Specifically, the plurality of electrodes may be attached to the polymer layer through the bonding agent or the adhesive. Here, the bonding agent may be formed on a portion or the entirety of the outer surface of the electrode.

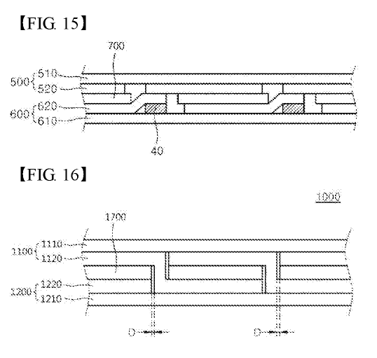

Next, a solar cell protective sheet according to yet another embodiment of the present invention will be described with reference to FIG. 14 and FIG. 15. FIG. 14 is a schematic sectional view of a solar cell protective sheet according to yet another embodiment of the present invention and FIG. 15 is a schematic sectional view of a solar cell module in which the solar cell protective sheet of FIG. 14 is used.

Referring to FIG. 14, the solar cell protective sheet according to this embodiment may further include a shielding member 40 interposed between the connecting section 19 of a unit electrode and a polymer layer 10, wherein the shielding member 40 may extend in the second direction.

Since the polymer layer 10 and the unit electrode according to this embodiment are substantially the same as the polymer layer and the unit electrode according to the above embodiment of the present invention, the shielding member 40 will be mainly described.

Referring to FIG. 14, the shielding member 40 is formed under one end of the unit electrode (i.e., under the connecting section) to reduce a height difference between electrodes in manufacture of a solar cell module. Referring to FIG. 15, in manufacture of a solar cell module using the solar cell protective sheet including the shielding member 40, a height difference between an electrode 520 of a first protective sheet 500 and an electrode 620 of a second protective sheet 600, which is caused by a solar cell 700, can be canceled out by the shielding member 40 of the second protective sheet 600, whereby stable electrical connection between the electrodes can be achieved and short circuit between the electrodes can be prevented. Since the polymer layer (and a glass substrate formed on the polymer layer) is transparent, electrodes connecting adjacent solar cells on a front surface of a solar cell module are visible from the outside. Accordingly, improvement in appearance of the solar cell module may be required depending on the location at which the solar cell module is installed. Here, the shielding member 40 may also serve to conceal the electrodes.

The shielding member 40 according to the present invention may be formed of an opaque material including at least one selected from among polyethylene terephthalate (PET), polypropylene (PP), polyimide (PI), poly(methyl methacrylate) (PMMA), polystyrene (PS), polyethylene (PE), polyvinylchloride (PVC), and ethylene vinyl acetate (EVA) to conceal electrodes connecting adjacent solar cells to one another, thereby improving appearance of a solar cell module. Particularly, the shielding member 40 may include or be coated with a functional additive to provide heat resistance, heat dissipation, durability, and discoloration resistance. The functional additive may include at least one selected from among a heat dissipation agent, a weathering agent, an insulator, an antioxidant, a UV stabilizer, a flame retardant, an antistatic agent, fillers, a colorant, a plasticizer, a heat stabilizer, an anti-blocking agent, a slip agent, and a nucleating agent.

In addition, the shielding member 40 may have a height (SH) of 50 μm to 450 μm, specifically 100 μm to 350 μm, more specifically 150 μm to 300 μm. Within this range, the shielding member can minimize a height difference between electrodes while exhibiting good shielding properties and durability. Further, the width of the shielding member may be properly adjusted depending on the distance between solar cells and/or the structure of a solar cell module.

Although FIG. 15 shows a solar cell module in which the shielding member 40 is used in one protective sheet, it should be understood that the present invention is not limited thereto. For example, both of the first and second protective sheets may include the shielding member. In this case, even when the shielding member is reduced in height (SH), a height difference between electrodes can be sufficiently reduced, and the structure of a solar cell module can be more stable since two protective sheets are both engaged in reduction of the height difference.

The solar cell protective sheet may further include a substrate and/or a back sheet on the other surface of the polymer layer 10 on which the plurality of electrodes is not formed, wherein the substrate may include general glass, tempered glass, heat-strengthened glass, a transparent polymer, or a polymer including glass fiber. Here, the back sheet may include any typical back sheet used in solar cell modules.

Solar Cell Protective Sheet Fabrication Method

Another aspect of the present invention relates to a method of fabricating a solar cell protective sheet.

In one embodiment, the method of fabricating the solar cell protective sheet may include laminating a plurality of electrodes 20 on a polymer layer 10. Here, the polymer layer 10 may be formed by a calendaring process, a co-extrusion process, a process in which a polymer layer composition is applied to a substrate, followed by drying or curing, a process in which polymer sheets are heated, followed by laminating, or a process in which polymer sheets are bonded to one another through a bonding agent or an adhesive.

In another embodiment, the method for fabricating the solar cell protective sheet may include applying a bonding agent to one surface of a polymer sheet in a predetermined pattern and forming a plurality of electrodes on the surface of the polymer sheet through the bonding agent. Here, each of the electrodes may include a conductive metal and a conductive material formed on the conductive metal.

In a further embodiment, the method for fabricating the solar cell protective sheet may include placing a shielding member 40 in a region of a surface of a polymer layer 10 corresponding to one end of each of a plurality of electrodes 20 and laminating the plurality of electrodes 20 on the polymer layer.

The method for fabricating the solar cell protective sheet according to the present invention may further include forming a substrate and/or a back sheet on the other surface of the polymer layer 10 on which the plurality of electrodes 20 is not formed, wherein the substrate may include general glass, tempered glass, heat-strengthened glass, a transparent polymer, or a polymer including glass fiber. Here, the back sheet may include any typical back sheet used in solar cell modules.

Solar Cell Module

A further aspect of the present invention relates to a solar cell module. Now, a solar cell module according to one embodiment of the present invention will be described with reference to FIG. 16. FIG. 16 is a schematic sectional view of a solar cell module according to one embodiment of the present invention.

Referring to FIG. 16, the solar cell module 1000 according to this embodiment may include a first protective sheet 1100, a second protective sheet 1200 opposite the first protective sheet 1100, and at least two solar cells 1700 formed between the first protective sheet 1100 and the second protective sheet 1200, wherein the first protective sheet 1100 or the second protective sheet 1200 may include the solar cell protective sheet according to the present invention.

The first protective sheet 1100 and the second protective sheet 1200 may be the solar cell protective sheet according to the present invention. For example, each of the first protective sheet 1100 and the second protective sheet 1200 may include a polymer layer 1110 or 1210 and a plurality of electrodes 1120 or 1220, wherein each of the electrodes may include a conductor and a conductive material.

Each of the first protective sheet 1100 and the second protective sheet 1200 includes the plurality of electrodes, wherein an electrode of the first protective sheet may be electrically connected to an electrode of the second protective sheet contacting a solar cell adjacent to the electrode of the first protective sheet.

Specifically, the plurality of electrodes may include at least two line electrodes arranged separate from one another in the second direction, wherein each of the line electrodes includes at least two unit electrodes arranged at constant intervals (D) in the first direction, and an electrode of the first protective sheet 1100 may be connected to an electrode of the second protective sheet 1200 contacting a solar cell adjacent to the electrode of the first protective sheet in the first direction to overlap the electrode of the second protective sheet by a length of 20 mm or less. As a result, adjacent solar cells can be connected to one another in series. In addition, the conductive material of the electrode 1120 of the first protective sheet and the conductive material of the electrode 1120 of the second protective sheet contacting the solar cell adjacent to the electrode of the first protective sheet are melted and joined together through a lamination process, such that electrical connection between the electrodes can be achieved.

In addition, the polymer layers 1110, 1210 of the first protective sheet 1100 and the second protective sheet 1200 may be fused around the electrodes 1120, 1220, respectively, through the lamination process. Since the conductive material of the first protective sheet 1100 is melted at a temperature of 200° C. or less, specifically 100° C. to 200° C., more specifically 150° C. to 200° C., which is a temperature at which the lamination process is performed, the conductive material of the first protective sheet 200 can be electrically connected to an upper side of the solar cell 1700 during the lamination process. Similarly, the conductive material of the second protective sheet 1200 can be electrically connected to a lower side of the solar cell 1700 during the lamination process.

The electrode 1120 of the first protective sheet 1100 may be connected to an upper electrode (e.g., a finger electrode, not shown) formed on the upper side of the solar cell 1700, thereby transmitting current reaching the upper electrode (e.g., a finger electrode) to the outside of the solar cell 1700. Specifically, the electrode 1120 of the first protective sheet 1100 may transmit the current reaching the upper electrode to another adjacent solar cell or an external component.

Further, the electrode 1220 of the second protective sheet 1200 may be connected to a lower electrode (not shown) formed at the lower side of the solar cell 1700, thereby transmitting current from the outside of the solar cell 1700 to the lower electrode. As a result, a plurality of solar cells can be electrically connected in series to one another.

Moreover, the solar cell module may further include a substrate formed on at least one of a front-side substrate thereof receiving light and a back-side substrate thereof, wherein the substrate may include general glass, tempered glass, heat-strengthened glass, a transparent polymer, or a polymer including glass fiber, and may further include a back sheet formed on the back surface thereof. Here, the back sheet may include any typical back sheet used in solar cell modules.

Solar Cell Module Fabrication Method

Yet another aspect of the present invention relates to a method of fabricating a solar cell module. In one embodiment, the method may include arranging at least two solar cells on a second protective sheet, placing a first protective sheet on the second protective sheet and the solar cell, and laminating the first protective sheet, the solar cell, and the second protective sheet at a temperature of 200° C. or less, specifically 150° C. to 200° C., more specifically 150° C. to 200° C.

The second protective sheet may include a polymer layer and a plurality of electrodes, wherein the plurality of electrodes may be arranged on the polymer layer in a predetermined pattern. Each of the electrodes may include a conductor and a conductive material formed on the conductor.

Specifically, in the method, at least two solar cells are arranged on the second protective sheet, and then the first protective sheet is placed over the second protective sheet and the solar cell, followed by lamination of the first protective sheet, the solar cell, and the second protective sheet at a temperature of 200° C. or less, specifically 150° C. to 200° C., more specifically 150° C. to 200° C. Here, the first protective sheet may be substantially the same as the second protective sheet.

The lamination process may be performed such that an electrode of the first protective sheet 200 and an electrode of the second protective sheet 300 contacting a solar cell adjacent to the electrode of the first protective sheet in the first direction overlap by a length of 20 mm or less. As a result, upper and lower electrodes of the solar cell can be electrically connected to the electrode of the first protective sheet and the electrode of the second protective sheet, respectively, and, particularly, the electrode of the first protective sheet can be electrically connected to the electrode of the second protective sheet contacting the solar cell adjacent to the electrode of the first protective sheet.

In one embodiment, the second protective sheet may be formed on the front substrate, and a front substrate or a back sheet may be formed on the first protective sheet. Here, the front substrate may include a substrate including general glass, tempered glass, heat-strengthened glass, a transparent polymer, or a polymer including glass fiber.

Although some embodiments have been described herein, it should be understood that these embodiments are provided for illustration only and are not to be construed in any way as limiting the present invention, and that various modifications, changes, alterations, and equivalent embodiments can be made by those skilled in the art without departing from the spirit and scope of the invention. The scope of the present invention should be defined by the appended claims and equivalents thereof.

1. A solar cell protective sheet comprising:
a polymer layer; and
a plurality of electrodes arranged on the polymer layer,
wherein the plurality of electrodes comprises at least two unit electrodes arranged separate from one another in a first direction, each of the unit electrodes being composed of a cell section and a connecting section.

2. The solar cell protective sheet according to claim 1, wherein the electrode comprises a protrusion formed at one end of the connecting section thereof and extending in a second direction.

3. The solar cell protective sheet according to claim 1, wherein the plurality of electrodes comprises at least two line electrodes arranged separate from one another in the second direction, each of the line electrodes comprising at least two unit electrodes arranged separate from one another in the first direction.

4. The solar cell protective sheet according to claim 3, wherein the connecting section comprises at least one portion not parallel to the first direction.

5. The solar cell protective sheet according to claim 3, wherein a unit electrode of a first line electrode and a unit electrode of a second line electrode are connected to one another at the connecting sections thereof.

6. The solar cell protective sheet according to claim 3, wherein the cell section comprises at least one portion not parallel to the first direction.

7. The solar cell protective sheet according to claim 3, wherein a unit electrode of a first line electrode and a unit electrode of a second line electrode are connected to one another in a semicircular shape at the connecting sections thereof, and the unit electrode of the second line electrode and a unit electrode of another adjacent line electrode are connected to one another in a semicircular shape at the connecting sections thereof, the unit electrodes being integrally formed with one another in the second direction.

8. The solar cell protective sheet according to claim 1, wherein the polymer layer comprises at least one selected from among an ethylene-vinyl acetate resin, a polyolefin resin, a polyester resin, a polyurethane resin, an ethylene copolymer resin, a silicone compound, and a silicone-based hybrid copolymer.

9. The solar cell protective sheet according to claim 1, wherein the electrode comprises a conductor and a conductive material formed on the conductor, the conductive material comprising an alloy having a melting point of 200° C. or less.

10. The solar cell protective sheet according to claim 9, wherein the conductor comprises copper (Cu), nickel (Ni), aluminum (Al) or at least two selected from copper (Cu), nickel (Ni), aluminum (Al), an anisotropic conductive film, anisotropic conductive pastes (CP), and activated carbon fiber (ACF).

11. The solar cell protective sheet according to claim 9, wherein the alloy having a melting point of 200° C. or less is an alloy of at least two selected from among bismuth (Bi), tin (Sn), silver (Ag), lead (Pb), cadmium (Cd), and indium (In).

12. The solar cell protective sheet according to claim 9, wherein the conductive material is formed on a portion or entirety of an outer surface of the conductor.

13. The solar cell protective sheet according to claim 1, wherein the plurality of electrodes is formed on the polymer layer through a bonding agent.

14. The solar cell protective sheet according to claim 13, wherein the bonding agent is formed on a portion or entirety of an outer surface of the electrode.

15. The solar cell protective sheet according to claim 1, further comprising:
a shielding member interposed between the connecting section and the polymer layer, the shielding member extending in a second direction.

16. The solar cell protective sheet according to claim 15, wherein the shielding member comprises at least one selected from among polyethylene terephthalate (PET), polypropylene (PP), polyimide (PI), poly(methyl methacrylate) (PMMA), polystyrene (PS), polyethylene (PE), polyvinylchloride (PVC), and ethylene vinyl acetate (EVA).

17. A method of fabricating a solar cell protective sheet, comprising
laminating a plurality of electrodes on a polymer layer.

18. A solar cell module comprising:
a first protective sheet;
a second protective sheet opposite the first protective sheet; and
at least two solar cells formed between the first protective sheet and the second protective sheet,
wherein the first protective sheet or the second protective sheet comprises the solar cell protective sheet according to claim 1.

19. The solar cell module according to claim 18, the connecting section of the first protective sheet is electrically connected to the connecting section of the second protective sheet contacting a solar cell adjacent to the connecting section of the first protective sheet.

20. A method of fabricating the solar cell module according to claim 18, comprising:
arranging the at least two solar cells on the second protective sheet;
placing the first protective sheet on the second protective sheet and the solar cells; and
laminating the second protective sheet, the solar cells, and the first protective sheet at a temperature of 200° C. or less.
